(19) United States
(12) Patent Application Publication
(10) Pub. No.: US 2025/0379069 A1
(43) Pub. Date: Dec. 11, 2025

(54) LIQUID PROCESSING APPARATUS

(71) Applicant: Tokyo Electron Limited, Tokyo (JP)

(72) Inventors: Yusaku HASHIMOTO, Koshi City (JP); Koki YOSHIMURA, Koshi City (JP); Yuki FUKUDA, Koshi City (JP)

(21) Appl. No.: 19/225,217

(22) Filed: Jun. 2, 2025

(30) Foreign Application Priority Data
Jun. 6, 2024 (JP) 2024-092337

(51) Int. Cl. H01L 21/67; G03F 7/30

(52) U.S. Cl. CPC H01L 21/67023; G03F 7/3021; G03F 7/3092

(57) ABSTRACT

A liquid processing apparatus includes a holder that holds and rotates a substrate, a liquid supply that supplies a processing liquid to an upper surface of the substrate held by the holder, a first cup body annularly provided on a lower surface side of the substrate held by the holder and below a peripheral edge of the substrate, and a second cup body annularly provided on an inner side of the first cup body and having a plurality of annular protrusions that is concentrically arranged on a side of an opposing surface facing a lower surface of the substrate and protrudes toward the lower surface of the substrate.

### CROSS-REFERENCE TO RELATED APPLICATION

This application is based upon and claims the benefit of priority from Japanese Patent Application No. 2024-092337, filed on Jun. 6, 2024, the entire contents of which are incorporated herein by reference.

### TECHNICAL FIELD

The present disclosure relates to a liquid processing apparatus.

### BACKGROUND

Conventionally, a liquid processing apparatus is known in which, while a substrate such as a semiconductor wafer is rotated, liquid processing is performed by supplying a processing liquid from above the rotating substrate to an upper surface of the substrate. Such a liquid processing apparatus recovers the processing liquid scattered from the substrate using an external cup and an internal cup arranged to surround the periphery of the rotating substrate.

In addition, there is a liquid processing apparatus in which an internal cup is divided into a first cup body provided on a lower surface side of a substrate and below a peripheral edge of the substrate and a second cup body provided on an inner side of the first cup body, and a protrusion protruding toward a lower surface of the substrate is provided on the second cup body (see Patent Document 1).

### Prior Art Document

### Patent Document

Patent Document 1: Japanese patent laid-open publication No. 2015-076534

### SUMMARY

According to one embodiment of the present disclosure, there is provided a liquid processing apparatus including a holder that holds and rotates a substrate, a liquid supply that supplies a processing liquid to an upper surface of the substrate held by the holder, a first cup body annularly provided on a lower surface side of the substrate held by the holder and below a peripheral edge of the substrate, and a second cup body annularly provided on an inner side of the first cup body and having a plurality of annular protrusions that is concentrically arranged on a side of an opposing surface facing a lower surface of the substrate and protrudes toward the lower surface of the substrate.

### BRIEF DESCRIPTION OF DRAWINGS

The accompanying drawings, which are incorporated in and constitute a part of the specification, illustrate embodiments of the present disclosure, and together with the general description given above and the detailed description of the embodiments given below, serve to explain the principles of the present disclosure.

FIG. 1 is a plan view illustrating a configuration of a liquid processing apparatus according to a first embodiment.

FIG. 2 is a cross-sectional view illustrating the configuration of the liquid processing apparatus according to the first embodiment.

FIG. 3 is an enlarged view illustrating the vicinity of a recovery cup according to the first embodiment.

FIG. 4 is a plan view illustrating a configuration of a second cup body according to the first embodiment.

FIG. 5 is a diagram illustrating an example of a state in which a protrusion structure is separated from the second cup body.

FIG. 6 is a cross-sectional view illustrating an example taken along arrow line A-A in FIG. 4.

FIG. 7 is a cross-sectional view illustrating an example taken along arrow line B-B in FIG. 4.

FIG. 8 is a cross-sectional view illustrating a configuration of the second cup body according to a second embodiment.

FIG. 9 is a cross-sectional view illustrating a configuration of a second cup body according to a third embodiment.

FIG. 10 is a cross-sectional view illustrating a configuration of a second cup body according to a fourth embodiment.

FIG. 11 is a cross-sectional view illustrating a configuration of the first cup body and the second cup body according to a fifth embodiment.

### DETAILED DESCRIPTION

Reference will now be made in detail to various embodiments, examples of which are illustrated in the accompanying drawings. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments.

Hereinafter, aspects for implementing a liquid processing apparatus according to the present disclosure (hereinafter referred to as “embodiments”) will be described in detail with reference to the drawings. The present disclosure is not limited to these embodiments. In addition, it is possible to combine respective embodiments appropriately unless process contents thereof are inconsistent. In the following embodiments, the same parts are denoted by like reference numerals, and redundant description thereof will be omitted.

In each drawing that will be referred to below, for clarity of explanation, there may be used a rectangular coordinate system in which an X-axis direction, a Y-axis direction, and a Z-axis direction, which are orthogonal to each other, are defined, and a positive direction of the Z-axis direction is regarded as a vertically upward direction. In addition, a rotational direction about a vertical axis as the center of rotation may be referred to as a θ direction. In the embodiments described below, expressions such as “constant”, “orthogonal”, “perpendicular”, and “parallel” may be used. These expressions, however, do not need to be exactly “constant”, “orthogonal”, “perpendicular”, and “parallel”. In other words, the above expressions allow for deviations in manufacturing accuracy, installation accuracy, and the like.

Conventionally, a liquid processing apparatus is known in which, while a substrate such as a semiconductor wafer is rotated, liquid processing is performed by supplying a processing liquid from above the rotating substrate to an upper surface of the substrate. Such a liquid processing apparatus recovers the processing liquid scattered from the substrate using an external cup and an internal cup arranged to surround the periphery of the rotating substrate.

In addition, there is a liquid processing apparatus in which an internal cup is divided into a first cup body provided on a lower surface side of a substrate and below a peripheral edge of the substrate and a second cup body provided on an inner side of the first cup body, and a protrusion protruding toward a lower surface of the substrate is provided on the second cup body. According to this liquid processing apparatus, the protrusion is brought close to the lower surface of the substrate, thereby preventing the processing liquid from flowing to the lower surface from an upper surface of the substrate.

However, in the above-described conventional technology, there are cases in which the processing liquid overflowing through the protrusion penetrates the lower surface of the substrate, and therefore, there remained room for improvement in sufficiently suppressing penetration of the processing liquid into the lower surface of the substrate.

Therefore, provision of a technology capable of suppressing penetration of the processing liquid into the lower surface of the substrate is anticipated.

### First Embodiment

### <Configuration of Liquid Processing Apparatus>

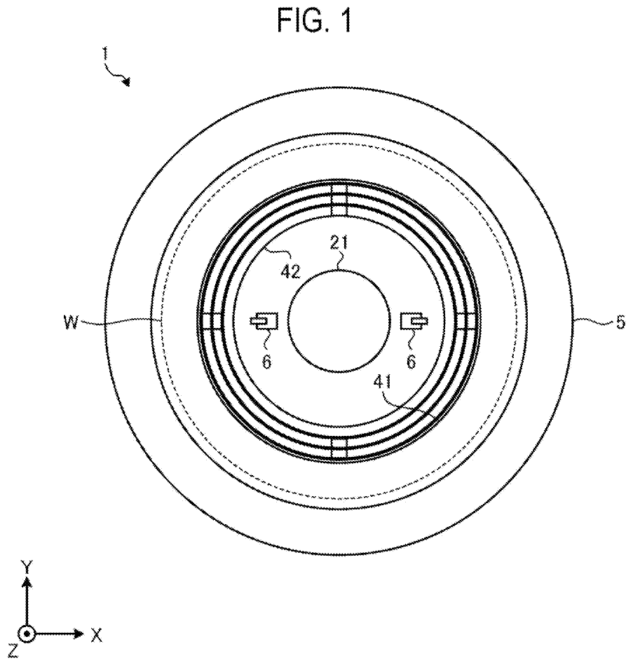

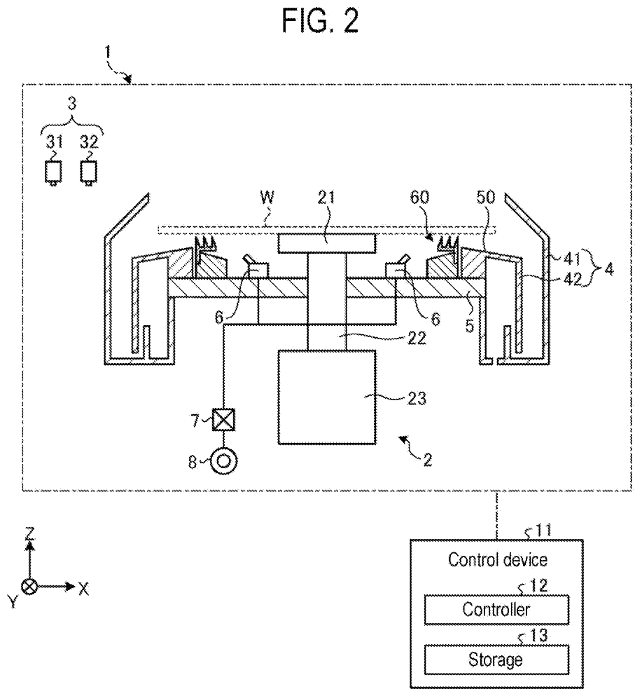

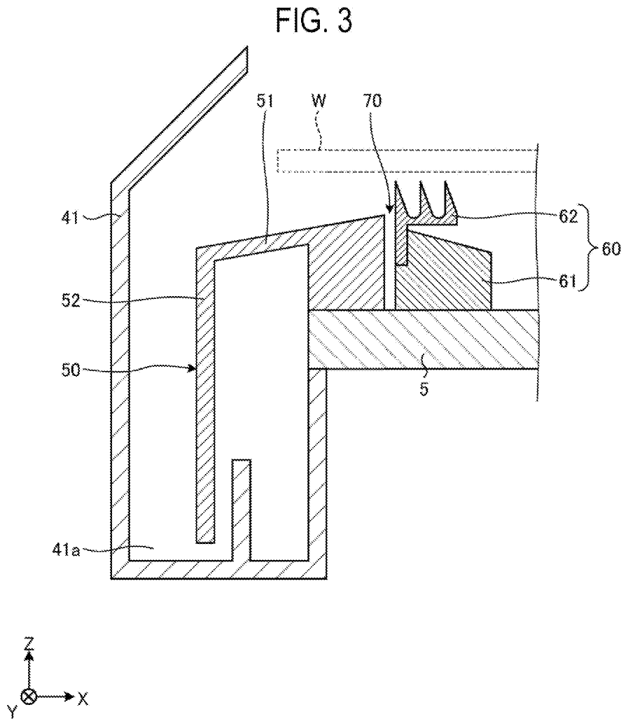

First, a configuration of a liquid processing apparatus 1 according to a first embodiment will be described with reference to FIGS. 1 to 3. FIG. 1 is a plan view illustrating the configuration of the liquid processing apparatus 1 according to the first embodiment. FIG. 2 is a cross-sectional view illustrating the configuration of the liquid processing apparatus 1 according to the first embodiment. FIG. 3 is an enlarged view illustrating the vicinity of a recovery cup 4 according to the first embodiment.

As illustrated in FIGS. 1 to 3, the liquid processing apparatus 1 according to the first embodiment is, for example, a developing processing apparatus and includes a substrate rotation portion 2 (e.g., a holder), an upper surface supply 3, and the recovery cup 4.

The substrate rotation portion 2 rotatably holds a wafer W (e.g., a substrate). Specifically, the substrate rotation portion 2 includes a vacuum chuck 21, a shaft 22, and a driving portion 23. The vacuum chuck 21 attracts and holds the wafer W through vacuum suction. The vacuum chuck 21 has a smaller diameter than the wafer W, and attracts and holds the center of a lower surface of the wafer W.

The shaft 22 horizontally supports the vacuum chuck 21 at a tip end portion thereof. The driving portion 23 is connected to a base end portion of the shaft 22. The driving portion 23 rotates the shaft 22 around a vertical axis and raises and lowers the shaft 22 and the vacuum chuck 21 supported by the shaft 22.

The upper surface supply 3 supplies a developer and a rinse liquid, which are processing liquids, to an upper surface of the wafer W. The upper surface supply 3 includes a developer supply nozzle 31 (e.g., a liquid supply) and a rinse liquid supply nozzle 32.

The developer supply nozzle 31 is positioned with a discharge port facing downward from above the wafer W and discharges the developer to the upper surface of the wafer W. The developer supply nozzle 31 is connected to a movement mechanism (not illustrated) and can move between a processing position above the wafer W and a standby position outside the processing position.

The rinse liquid supply nozzle 32 is positioned with a discharge port facing downward from above the wafer W and discharges the rinse liquid to the upper surface of the wafer W. The rinse liquid supply nozzle 32 is connected to a movement mechanism (not illustrated) and can move between a processing position above the wafer W and a standby position outside the processing position. In addition, as the rinse liquid, for example, deionized water (DIW) can be used.

The recovery cup 4 is provided to surround an outer side of the wafer W and recovers droplets of the processing liquid scattered from the wafer W. The recovery cup 4 has an outer cup 41 and an inner cup 42.

The outer cup 41 annularly covers the periphery of the wafer W held by the substrate rotation portion 2. The outer cup 41 is provided to surround, for example, a lateral side of the wafer W.

The inner cup 42 is arranged inside the outer cup 41 and is arranged below the wafer W held by the substrate rotation portion 2. The inner cup 42 is composed of a first cup body 50 and a second cup body 60 provided inside the first cup body 50.

The first cup body 50 and the second cup body 60 are detachably attached to a disc-shaped base 5, for example, by a fastening mechanism such as a screw. The base 5 is provided with a lower surface rinse liquid supply nozzle 6. The lower surface rinse liquid supply nozzle 6 is connected to a rinse liquid supply source 8 via a flow rate regulating mechanism 7 such as a valve and discharges a rinse liquid to the lower surface of the wafer W. The lower surface rinse liquid supply nozzle 6 supplies the rinse liquid to a position on the lower surface of the wafer W that is located inside the second cup body 60.

The first cup body 50 is annularly provided on a lower surface side of the wafer W and below a peripheral edge of the wafer W. The first cup body 50 has an annular inclined wall 51 that is inclined downward and outward from a position facing and close to a peripheral portion of the lower surface side of the wafer W, and an annular vertical wall 52 that extends downward continuously from a lower edge of the inclined wall 51. The inclined wall 51 and the vertical wall 52 guide a processing liquid dripped from the wafer W to a liquid receiving portion 41a of the outer cup 41. The liquid receiving portion 41a is provided with a drain port for discharging the processing liquid to the outside.

The second cup body 60 is annularly provided on the inner side of the first cup body 50. The second cup body 60 includes a main body 61 formed in an annular shape and a protrusion structure 62 detachably provided above the main body 61. A detailed configuration of the second cup body 60 will be described later.

A discharge path 70, which is an annular space, is formed between the first cup body 50 and the second cup body 60. A drain port (not illustrated) is provided below the discharge path 70. The developer blocked by the protrusion structure 62 of the second cup body 60 is discharged to the outside from the drain port via the discharge path 70. In addition, the position of the drain port is not limited to a position below the discharge path 70 and may be formed, for example, on the surface of the base 5 on the inner side of the second cup body 60.

The liquid processing apparatus 1 further includes a control device 11. The control device 11 is, for example, a computer and includes a controller 12 and a storage 13.

The storage 13 is realized by, for example, a semiconductor memory element such as a random access memory (RAM) or a flash memory, or a storage device such as a hard disk or an optical disc and stores a program that controls various processes executed in the liquid processing apparatus 1.

The controller 12 includes a microcomputer or various circuits having a central processing unit (CPU), a read only memory (ROM), a random access memory (RAM), an input/output port, and the like. The controller 12 controls the operation of the liquid processing apparatus 1 by reading and executing the program stored in the storage 13.

In addition, such a program may be recorded in a non-transitory computer-readable storage medium and installed in the storage 13 of the control device 11 from the storage medium. The computer-readable storage medium includes, for example, a hard disk (HD), a flexible disk (FD), a compact disc (CD), a magneto-optical disc (MO), a memory card, etc.

### <Detailed Configuration of Second Cup Body>

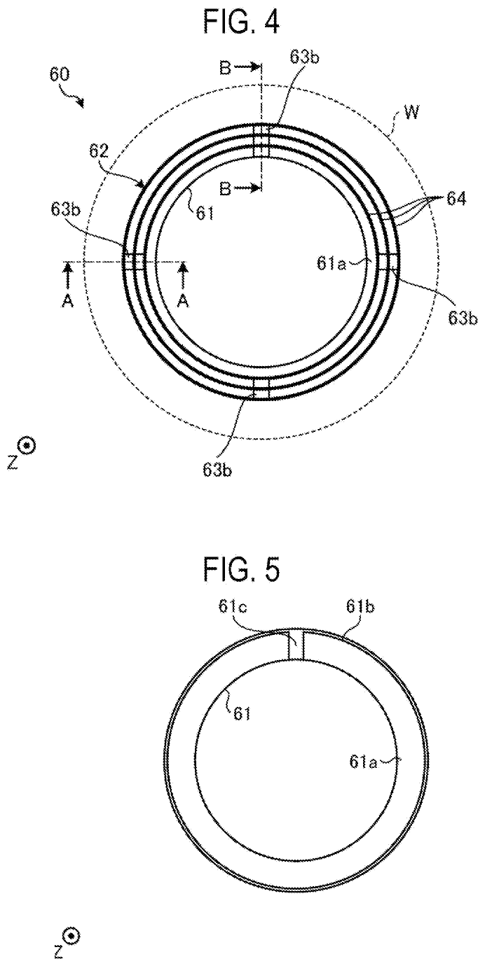

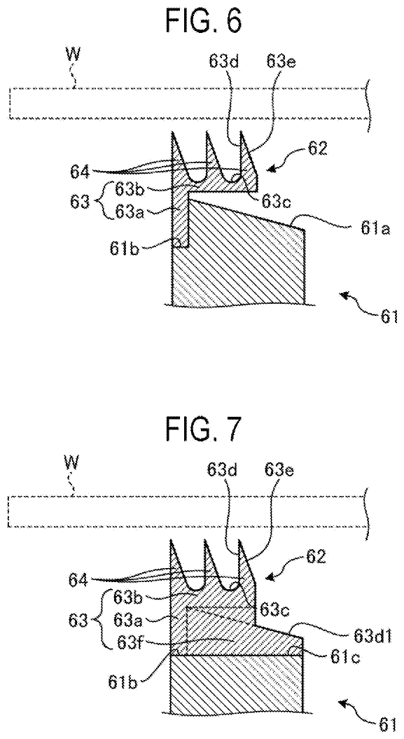

Next, the detailed configuration of the second cup body 60 will be described with reference to FIGS. 4 to 7. FIG. 4 is a plan view illustrating a configuration of the second cup body 60 according to the first embodiment. FIG. 5 is a diagram illustrating an example of a state in which the protrusion structure 62 is separated from the second cup body 60. FIG. 6 is a cross-sectional view illustrating an example taken along arrow line A-A in FIG. 4. FIG. 7 is a cross-sectional view illustrating an example taken along arrow line B-B in FIG. 4. In addition, the cross-sectional views illustrated in FIGS. 6 and 7 correspond to side cross-sectional views perpendicular to a circumferential direction of the second cup body 60.

As illustrated in FIGS. 4 and 5, the second cup body 60 includes the annular main body 61 and the protrusion structure 62 detachably provided on the main body 61.

The main body 61 faces a lower surface of the wafer W at an upper surface 61a. That is, the upper surface 61a of the main body 61 serves as an opposing surface facing the lower surface of the wafer W. In addition, the upper surface 61a of the main body 61 is inclined downward from an outer peripheral surface of the main body 61 toward an inner peripheral surface of the main body 61. An annular stepped portion 61b is formed on an outer periphery of the upper surface 61a.

The protrusion structure 62 includes a base member 63 and a plurality (herein, for example, three) of protrusions 64. The base member 63 is a support member that supports the protrusions 64 from below and includes an annular body 63a fitted into the stepped portion 61b and a plurality (herein, four) of arm portions 63b that extends in a radial direction of the annular body 63a from an inner peripheral surface of the annular body 63a above the upper surface 61a of the main body 61. The plurality of arm portions 63b is arranged at intervals in a circumferential direction of the annular body 63a.

The plurality of protrusions 64 has an annular shape. The plurality of protrusions 64 protrudes toward the lower surface of the wafer W. Each of the plurality of protrusions 64 includes a tip end (upper end) having a knife edge shape. The heights of tip ends of the plurality of protrusions 64 may be equal. An end surface (upper surface) of each of the plurality of protrusions 64 may be a flat surface. The distance between the tip end of each of the plurality of protrusions 64 and the lower surface of the wafer W is set to a prescribed distance such that a liquid seal is formed by the developer in a space between the tip end of each of the plurality of protrusions 64 and the lower surface of the wafer W. The number of the plurality of protrusions 64 is not limited to three and may be two or more.

The plurality of protrusions 64 is concentrically arranged on the annular body 63a and the plurality of arm portions 63b in a radial direction of the annular body 63a and is detachably provided with respect to the main body 61 via the annular body 63a and the plurality of arm portions 63b.

In this way, in the present embodiment, the second cup body 60 has the plurality of annular protrusions 64 concentrically arranged on the upper surface 61a side of the main body 61 and protruding toward the lower surface of the wafer W. As a result, the liquid seal by the developer is formed in the space between the tip end of each of the plurality of protrusions 64 and the lower surface of the wafer W, thereby preventing the developer from flowing from the upper surface to the lower surface of the wafer W. Therefore, the developer can be prevented from penetrating the lower surface of the wafer W.

In addition, the plurality of protrusions 64 is detachably provided with respect to the main body 61 from the upper surface 61a side of the main body 61. Specifically, the plurality of protrusions 64 is detachably provided with respect to the main body 61 via the base member 63. Accordingly, when regular maintenance of the second cup body 60 is performed, the protrusion structure 62 (i.e., the base member 63 and the plurality of protrusions 64) of the second cup body 60 can be separated from the main body 61 of the second cup body 60, so that the replacement operation of the plurality of protrusions 64 can be easily performed.

As illustrated in FIG. 6, in a state in which the plurality of protrusions 64 is mounted to the main body 61 via the base member 63, two of the plurality of protrusions 64 arranged on the plurality of arm portions 63b are spaced apart from the upper surface 61a of the main body 61. That is, a gap is formed between a lower end of each of the two protrusions 64 arranged on the plurality of arm portions 63b and the upper surface 61a of the main body 61. With this configuration, the developer dropped from the two protrusions 64 onto the upper surface 61a of the main body 61 can flow smoothly to a lower end side of the upper surface 61a of the main body 61, thereby improving drainage properties.

Each of the plurality of protrusions 64 has a vertical surface 63d positioned on an outer peripheral surface of the annular body 63a and an inclined surface 63e inclined downward from an upper edge of the vertical surface 63d toward an inner peripheral surface side of the annular body 63a. Since each of the plurality of protrusions 64 has the vertical surface 63d, the liquid seal by the developer is more favorably formed in the space between the tip end of each of the plurality of protrusions 64 and the lower surface of the wafer W, so that the developer can be stably prevented from flowing from the upper surface to the lower surface of the wafer W. Accordingly, penetration of the developer into the lower surface of the wafer W can be more reliably suppressed. In addition, since each of the plurality of protrusions 64 has the inclined surface 63e, the rinse liquid supplied to the lower surface of the wafer W from the lower surface rinse liquid supply nozzle 6 can easily flow to the outside of the second cup body 60. Therefore, the cleaning efficiency of the developer by the rinse liquid on the lower surface of the wafer W can be improved.

In addition, each of the plurality of arm portions 63b has a curved surface 63c that is concave toward the upper surface 61a of the main body 61 at a position sandwiched between the adjacent protrusions 64 when viewed in side cross section. As a result, the developer dropped from the adjacent protrusion 64 to the arm portion 63b can be guided from the arm portion 63b toward the upper surface 61a of the main body 61, thereby improving drainage properties.

As illustrated in FIG. 5, a groove 61c that extends in a radial direction of the main body 61 is formed on the upper surface 61a of the main body 61. The groove 61c is connected to the stepped portion 61b formed on an outer periphery of the main body 61. The groove 61c extends from the stepped portion 61b to an inner peripheral surface of the main body 61.

As illustrated in FIG. 7, the base member 63 has another arm portion 63f that extends in the radial direction of the annular body 63a from the inner peripheral surface of the annular body 63a at a position lower than the plurality of arm portions 63b. The another arm portion 63f extends from the inner peripheral surface of the annular body 63a to the inner peripheral surface of the main body 61. The another arm portion 63f is fitted into the groove 61c of the main body 61. In a state in which the plurality of protrusions 64 is mounted to the main body 61 via the base member 63, the another arm portion 63f of the base member 63 is fitted into the groove 61c of the main body 61, thereby suppressing misalignment of the base member 63.

In addition, the another arm portion 63f has an inclined surface 63d1 that is continuous with the upper surface 61a of the main body 61 in a state in which the another arm portion 63f is fitted into the groove 61c of the main body 61. With this configuration, inhibiting fluidity of the developer on the upper surface 61a of the main body 61 by the another arm portion 63f can be suppressed, thereby improving drainage properties.

The another arm portion 63f is integrally formed with at least one arm portion 63b among the plurality of arm portions 63b by overlapping with it. With this configuration, the another arm portion 63f can be reinforced, thereby further suppressing misalignment of the base member 63.

In this way, in the liquid processing apparatus 1 according to the first embodiment, the second cup body 60 is provided on the inner side of the first cup body 50, and the plurality of annular protrusions 64 is concentrically arranged on the upper surface 61a side facing the lower surface of the wafer W. As a result, since the developer flowing from the upper surface to the lower surface of the wafer W can be blocked by the plurality of protrusions 64, the developer can be prevented from penetrating the lower surface of the wafer W.

### Second Embodiment

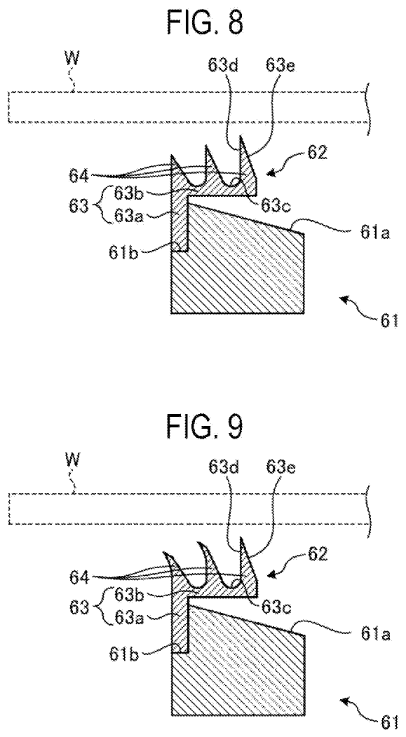

FIG. 8 is a cross-sectional view illustrating a configuration of the second cup body 60 according to a second embodiment. In the first embodiment described above, while an example in which the heights of the tip ends of the plurality of protrusions 64 relative to the base member 63 are equal, the heights of the tip ends of the plurality of protrusions 64 relative to the base member 63 may be different.

For example, as illustrated in FIG. 8, the height of a tip end of at least one protrusion 64 among the plurality of protrusions 64 may be lower than the heights of the tip ends of the other protrusions 64 arranged radially inside that protrusion 64 relative to the base member 63. In the example of FIG. 8, as the plurality of protrusions 64 is positioned closer to the peripheral edge of the wafer W, the heights of the tip ends of the plurality of protrusions 64 relative to the base member 63 become lower. With this configuration, even if wafer warpage occurs in which the peripheral edge of the wafer W curves downward, it becomes difficult for the plurality of protrusions 64 to come into contact with the lower surface of the wafer W, thereby suppressing damage to the wafer W.

### Third Embodiment

FIG. 9 is a cross-sectional view illustrating a configuration of the second cup body 60 according to a third embodiment. In the second embodiment described above, an example has been described in which the height of the tip end of at least one protrusion 64 among the plurality of protrusions 64 is lower than the heights of the tip ends of the other protrusions 64 arranged inside the protrusion 64 relative to the base member 63. In addition, in the third embodiment, the tip end of at least one protrusion 64 among the plurality of protrusions 64 may be bent radially outward.

For example, as illustrated in FIG. 9, the tip ends of two protrusions 64, excluding the innermost protrusion 64 among the plurality of protrusions 64, are bent radially outward. With this configuration, since it becomes difficult for the plurality of protrusions 64 and the lower surface of the wafer W to come into contact with each other, damage to the wafer W can be further suppressed.

### Fourth Embodiment

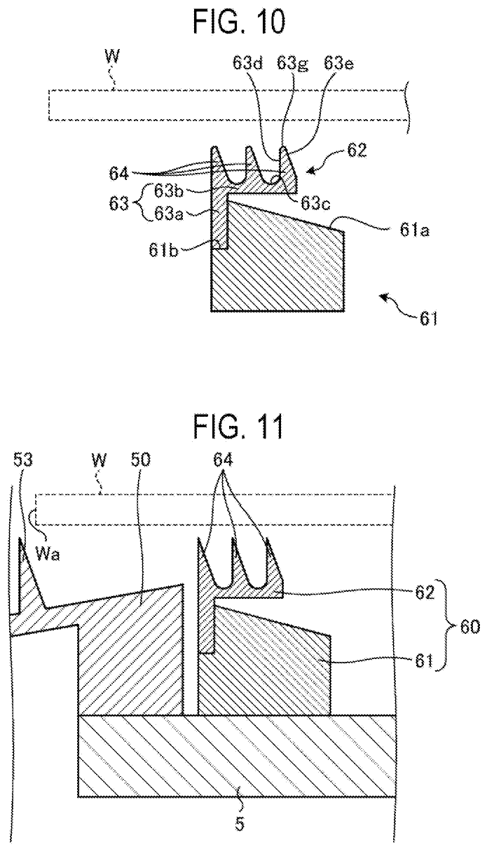

FIG. 10 is a cross-sectional view illustrating a configuration of the second cup body 60 according to a fourth embodiment. As illustrated in FIG. 10, a tip end of at least one protrusion 64 among the plurality of protrusions 64 has a rounded end surface 63g. In an example of FIG. 10, tip ends of all of the plurality of protrusions 64 have the rounded end surfaces 63g. With this configuration, when the protrusions 64 and the lower surface of the wafer W come into contact with each other, external force applied to the protrusions 64 is alleviated, thereby suppressing damage to the wafer W.

### Fifth Embodiment

FIG. 11 is a cross-sectional view illustrating a configuration of the first cup body 50 and the second cup body 60 according to a fifth embodiment. In each of the above-described embodiments, while an example has been described in which, in the second cup body 60, the plurality of annular protrusions 64 is arranged on the upper surface 61a side facing the lower surface of the wafer W, other protrusions may be arranged below a peripheral edge Wa of the wafer W or outside the peripheral edge of the wafer W. For example, as illustrated in FIG. 11, in the first cup body 50, an annular protrusion 53 may be arranged at a portion located below the peripheral edge Wa of the wafer W.

In this way, by providing the annular protrusion 53 on the first cup body 50, the developer flowing from the upper surface of the wafer W via the peripheral edge Wa to the lower surface of the wafer W can be more stably blocked. Therefore, penetration of the developer into the lower surface of the wafer W can be further suppressed.

### Other Embodiments

In each of the embodiments described above, while an example has been described in which the main body 61 and the protrusion structure 62 in the second cup body 60 are formed separately, the main body 61 and the protrusion structure 62 may be integrally formed.

As described above, the liquid processing apparatus (e.g., the liquid processing apparatus 1) according to the embodiment includes a holder (e.g., the substrate rotation portion 2), a liquid supply (e.g., the developer supply nozzle 31), a first cup body (e.g., the first cup body 50), and a second cup body (e.g., the second cup body 60). The holder holds and rotates a substrate (e.g., the wafer W). The liquid supply supplies a processing liquid (e.g., the developer) to an upper surface of the substrate held by the holder. The first cup body is annularly provided on a lower surface side of the substrate held by the holder and below a peripheral edge of the substrate. The second cup body is annularly provided on an inner side of the first cup body and has a plurality of annular protrusions (e.g., the protrusions 64) that is concentrically arranged on an opposing surface (e.g., the upper surface 61a) side facing a lower surface of the substrate and protrudes toward the lower surface of the substrate. As a result, penetration of the developer into the lower surface of the wafer W can be suppressed.

According to the present disclosure in some embodiments, it is possible to suppress penetration of a processing liquid into a lower surface of a substrate.

While certain embodiments have been described, these embodiments have been presented by way of example only, and are not intended to limit the scope of the disclosure. Indeed, the embodiments described herein may be embodied in a variety of other forms. Furthermore, various omissions, substitutions and changes in the form of the embodiments described herein may be made without departing from the spirit of the disclosure. The accompanying claims and their equivalents are intended to cover such forms or modifications as would fall within the scope and spirit of the disclosure.

What is claimed is:

1. A liquid processing apparatus comprising:
a holder that holds and rotates a substrate;
a liquid supply that supplies a processing liquid to an upper surface of the substrate held by the holder;
a first cup body annularly provided on a lower surface side of the substrate held by the holder and below a peripheral edge of the substrate; and
a second cup body annularly provided on an inner side of the first cup body and having a plurality of annular protrusions that is concentrically arranged on a side of an opposing surface facing a lower surface of the substrate and protrudes toward the lower surface of the substrate.

2. The liquid processing apparatus of claim 1, wherein the second cup body has a main body formed in an annular shape, and
wherein the plurality of protrusions is detachably provided with respect to the main body.

3. The liquid processing apparatus of claim 2, wherein the main body includes a stepped portion annularly formed on an outer periphery of the opposing surface,
wherein the second cup body includes a base member having an annular body fitted into the stepped portion and a plurality of arm portions extending in a radial direction of the annular body from an inner peripheral surface of the annular body above the opposing surface, and
wherein the plurality of protrusions is concentrically arranged on the annular body and the plurality of arm portions in the radial direction of the annular body, and is detachably provided with respect to the main body via the base member.

4. The liquid processing apparatus of claim 3, wherein one or more protrusions arranged on the plurality of arm portions are spaced apart from the opposing surface of the main body.

5. The liquid processing apparatus of claim 3, wherein each of the plurality of arm portions has a curved surface that is concave toward the opposing surface at a position sandwiched between adjacent protrusions when viewed in side cross section perpendicular to a circumferential direction of the main body.

6. The liquid processing apparatus of claim 3, wherein the main body has a groove formed on the opposing surface and extending in a radial direction of the main body,
wherein the base member has another arm portion extending in the radial direction of the annular body from the inner peripheral surface of the annular body at a position lower than the plurality of arm portions, and
wherein the another arm portion is fitted into the groove.

7. The liquid processing apparatus of claim 6, wherein the opposing surface of the main body is inclined downward from an outer peripheral surface of the main body toward an inner peripheral surface of the main body, and
wherein the another arm portion has an inclined surface that is continuous with the opposing surface in a state in which the another arm portion is fitted into the groove.

8. The liquid processing apparatus of claim 6, wherein the plurality of arm portions is arranged at intervals in a circumferential direction of the annular body, and
wherein the another arm portion is integrally formed with at least one arm portion among the plurality of arm portions by overlapping with the at least one arm portion.

9. The liquid processing apparatus of claim 1, wherein a height of a tip end of at least one protrusion among the plurality of protrusions is lower than heights of tip ends of the other protrusions arranged radially inside the at least one protrusion.

10. The liquid processing apparatus of claim 9, wherein the tip end of at least one protrusion among the plurality of protrusions is bent radially outward.

11. The liquid processing apparatus of claim 1, wherein a tip end of at least one protrusion among the plurality of protrusions has a rounded end surface.
